(19) United States
(12) Patent Application Publication
(10) Pub. No.: US 2011/0134964 A1
(43) Pub. Date: Jun. 9, 2011

(54) FREQUENCY SYNTHESIZER AND CONFIGURATION FOR AN ENHANCED FREQUENCY-HOPPING RATE

(75) Inventors: Remco Cornelis Herman van de Beek, Eindhoven (NL); Dominicus Martinus Wilhelmus Leenaerts, Riethoven (NL)

(73) Assignee: NXP B.V., Eindhoven (NL)

(21) Appl. No.: 13/059,460

(22) PCT Filed: Aug. 12, 2009
(86) PCT No.: PCT/IB09/53558

§ 371 Date: Feb. 17, 2011

(30) Foreign Application Priority Data
Aug. 21, 2008 (EP) 08162774.7
Aug. 12, 2009 (IB) PCT/IB2009/053558

(51) Int. Cl. H04B 1/00; G01R 23/02; H03D 13/00

(52) U.S. Cl. 375/132; 327/46; 327/45; 327/40; 375/E01.034

(57) ABSTRACT

A frequency generating arrangement for generation of at least two predetermined frequencies is introduced. The arrangement comprises a phase locked loop circuit with at least two control value storage units and at least one controlled oscillator unit, wherein the control value storage units being configured to selectively output a control signal to the at least one voltage controlled oscillator unit, causing generation of one of the at least two predetermined frequencies. Frequency generating system for generation of ultra-fast hopping-frequency sequences comprises at least a first and a second frequency generating arrangement and further a controlling unit and a multiplexer unit for selectively connecting only one of the outputs of the two frequency generating arrangements with an output of the system. The controlling unit can be configured to control the system to generate a predetermined frequency sequence by controlling the two frequency generating arrangements such that during the period, in which one of the frequency generating arrangements is connected with the output of the system, the other frequency generating arrangement is controlled to lock to a next predetermined frequency of the predetermined frequency sequence, and to control the multiplexer unit pass the output of the other frequency generating arrangement to the system output after a predetermined time period; and repeating the controlling step in order to generate the predetermined frequency sequence.

### FIELD OF THE INVENTION

The present invention relates, in general, to the field of frequency synthesizers. The invention relates, in particular, to configuration of frequency synthesizers, which provide for enhanced frequency hopping rates.

### BACKGROUND OF THE INVENTION

Certain communication standards, e.g. spread spectrum systems as for instance CDMA or Bluetooth just to name some examples, employ so-called frequency hopping as part of their physical level protocol. Frequency hopping is also used in spread spectrum techniques where energy generated in a particular bandwidth is purposely spread in the frequency domain, i.e. the generated signal has a wider bandwidth. Spread spectrum techniques are used for a variety of reasons, including inter alia the establishment of secure communications, increasing resistance to interference etc.

Frequency hopping means to shift a carrier frequency periodically or randomly among a plurality of different predefined frequencies. In order to receive the transmitted information, details as the sequence of the used frequencies as well as the timing of the respective frequency shifts have to be known in advance to the devices for reception of the information. Thus receiving devices must comprise corresponding reception circuitries configured for detecting and decoding of the received signals in accordance with the used frequency hopping sequence.

Accordingly, communication devices of this kind, i.e. receivers, transmitters or transceivers, generally comprise one or more phase locked loop (PLL) circuits acting as frequency generators. Said PLL circuits comprise at least a reference frequency source such as a crystal, a phase comparator, a loop filter, a voltage controlled oscillator (VCO) and often a controllable frequency divider. Since operation of PLL circuits and VCOs is well known to those skilled in the art, they are herein only briefly explained later on.

Depending on the purpose of the communication protocol, frequencies may be shifted up to more than thousand times a second. This poses a challenge on the frequency generator of the communication device that targets such a standard. In some use cases, changing the carrier frequency must happen so fast that a single phase-locked loop circuit cannot be employed due to limits in its lock transient. The lock transient denominates the portion of the signal from leaving the tolerance band of the former generated frequency step until being stable within the tolerance band of the successive frequency step.

An example for applications with carrier frequencies switching at high rates is WiMedia Ultra-Wide Band, which is an ISO-published radio standard for high-speed ultra-wideband (UWB) wireless connectivity. The first implementations of WiMedia UWB serve as the foundation for Wireless USB.

As illustrated in FIG. 1A, a hopping transient in WiMedia UWB must be shorter than 9.5 ns. Further information can be gathered from the document “Standard ECMA-368; High rate Ultra Wideband PHY and MAC Standard”, December 2005, which is, for instance, available in the Internet at http://www.ecma-international.org/publications/standards/Ecma-368.htm.

One straight forward solution is to use two PLL circuits rather than one, in a so-called ping-pong architecture, which is illustrated in FIG. 1B, where one of the two PLL circuits PLL X and PLL Y provides the actual local oscillator (LO) signal for frequency conversion, while the other PLL is prepared to take that role by locking to the next required LO frequency. Frequency hopping then is implemented by switching a multiplexer unit MUX, which has as inputs the respective output of the VCOs VCO X and VCO Y and forwards one thereof to an output of the MUX. This results in a controlled interchanging of the roles of both PLL circuits. The ping-pong architecture may relax the lock transient time of the PLL circuits from the hopping transient, i.e. the 9.5 ns as required in the WiMedia UWB example, to the time between two hops, which is about 312.5 ns, as illustrated in FIG. 1A.

In some systems, however, even such a ping-pong scheme poses severe challenges on the lock transients of the PLL circuits, because the time between hops may still be short—although considerably longer than the maximum hop transient time. The aforementioned WiMedia UWB is again a good example, where the fastest time between two frequency hops may be around 312.5 ns. This means that the requirement for the PLL lock transient is reduced from about 9 ns to around 300 ns, which is still a challenging requirement.

One common solution is to use some form of single-side-band (SSB) mixing to generate carriers of different frequencies by changing multiplexers only, such an example is given by D. Leenaerts et al. in “A SiGe BiCMOS lns Fast Hopping Frequency Synthesizer for UWB radio”, in IEEE ISSCC Dig. Tech. Papers, February 2005, pp. 202-203.

Another approach for the scenario of the WiMedia UWB example is to employ three PLL circuits that are ON simultaneously, as described in “A 0.13 μm CMOS UWB Transceiver”, in IEEE ISSCC Dig. Tech. Papers, February 2005, pp. 216-217, where each PLL circuit generates one of the three required LO frequencies of a band group. This approach is illustrated in FIG. 1C, which shows a circuit having three parallel PLL circuits. Since all the PLL circuits are basically similar construed, corresponding elements in the second and third PLL circuit are indicated by the same numbers as in the first PLL circuit, but primed and double primed, respectively. The VCOs have been denoted by 110, 111, 112 for better differentiation.

The basic function of a PLL is briefly explained as follows. The output frequency of VCO 110 is compared with reference frequency signal 101 generated by a crystal or the like in a phase comparator 102. The comparison results in a respective control voltage for controlling or adjusting the VCO 110 and thus its output frequency. A low pass filter network 103 prevents the PLL circuit itself from oscillating. By converting the frequency signal of the VCO 110 in a frequency divider 104 before feeding back to the phase comparator 102, a variety of frequencies may be generated by the PLL circuit though having only a fixed reference signal source 101. Accordingly, the system shown in FIG. 1 can provide three different frequencies in accordance to the settings of the respective dividers 104, 104′, and 104″, simultaneously.

However, both above discussed solutions have their own drawbacks and limitations. SSB-mixing introduces many spurious tones in the LO spectrum that can only be avoided when performing extensive filtering both before as well as after the SSB mixer. Further, the filters consume power and/or large area, if LC-filtering is used for example. With the filters added, meeting phase noise specifications can be hard due to the many stages in the LO path. The disadvantages of three complete PLL circuits used in parallel are both area consuming as well as power consuming.

U.S. Pat. No. 4,511,858 discloses a PLL circuit where values of a “pre-positioning voltage” are stored and used the next time a frequency is required. This document also shows a multiple PLL system where the control processes are shared to generate multiple frequencies.

### SUMMARY OF THE INVENTION

It is one object of the present invention to provide a frequency synthesizer arrangement, which enables fast frequency hopping so that to be capable of providing a plurality of frequencies at high frequency hopping rates with a minimum of lock transient time and requiring a minimum of hardware.

The object can be achieved by a frequency generating arrangement for generation of at least two predetermined frequencies according to claim 1.

Accordingly, the frequency generating arrangement comprises a phase locked loop circuit with at least two control value storage units and at least one controlled oscillator unit; wherein the control value storage units being configured to selectively output a control signal to the at least one controlled oscillator unit, causing generation of one of the at least two predetermined frequencies.

It is worth to be noted that the controllable oscillator can be a voltage controlled oscillator, i.e. the control signal being a voltage, but can be controlled by other means than a control voltage, such as a digital control word, i.e. in case of a digitally controlled oscillator (DCO) or even a current, i.e. in case of a current controlled oscillator (CCO).

In certain embodiments of the frequency generating arrangement, the phase locked loop circuit comprises a multi switch for connecting and disconnecting the output of one of the at least two control value storage units with the at least one controlled oscillator unit.

In another embodiment of the frequency generating arrangement, the phase locked loop circuit further comprises for each control value storage unit a corresponding controlled oscillator unit connected thereto, and a multi switch for connecting and disconnecting the output of one of the controlled oscillator units with the output of the frequency generating arrangement.

Preferably, the frequency generating arrangement further comprises a controlling unit configured to control the switching of the multi switch such that the frequency generating arrangement outputs a predetermined frequency sequence with a predetermined timing.

In a further development of the frequency generating arrangement, the at least two control value storage units are integrated together in a memory bank, which is configured for storing information corresponding to the respective predetermined control values of the control value storage units. Furthermore, the memory bank can be configured to selectively output one of the control values by means of, for example, a respective control signal inputted to the memory bank.

In certain embodiments of the frequency generating arrangement, a track-and-hold or sample-and-hold circuit is used as control value storage unit. Alternatively, the control value storage unit may be implemented by one of analog components, digital components, or a hybrid thereof. In case of the control value storage means comprising analogue and digital components, the digital storage components, for example a digital register, is arranged to store a first part of the control value for coarse tuning of a respective controlled oscillator unit connected thereto and the analogue component, for example a capacitor in case of a voltage controlled oscillator with a voltage being used as control signal, is arranged to store a second part of the control value for fine tuning of the controlled oscillator unit.

The object can further be achieved by a frequency generating system according to claim 9, which comprises a first and a second frequency generating arrangement for generation of at least two predetermined frequencies.

Accordingly, the frequency generating system comprises the first and the second frequency generating arrangement, at least one controlling unit and a multiplexer unit for selectively connecting only one of the outputs of the two frequency generating arrangements with an output of the system; wherein the controlling unit is further configured to control the system to generate a predetermined frequency sequence by controlling the two frequency generating arrangements such that during the period, in which one of the frequency generating arrangements is connected with the output of the system, the other frequency generating arrangement is controlled to lock to a next predetermined frequency of the predetermined frequency sequence, and to control the multiplexer unit pass the output of the other frequency generating arrangement to the system output after a predetermined time period; and repeating the controlling step in order to generate the predetermined frequency sequence.

The system is applicable in a communication device, which is configured for communication in accordance with a communication protocol in which a predetermined hopping frequency sequence is used. Such communication protocols may be Wi-Fi, Bluetooth, Code division multiple access (CDMA), Frequency-hopping spread spectrum (FHSS) or direct-sequence spread spectrum (DSSS) as used by the Wireless Ethernet standard IEEE 802.11, time-hopping spread spectrum (THSS), chirp spread spectrum (CSS), and combinations thereof, and Ultra-wideband (UWB), just to name some actual examples.

The object can further be achieved by a method for generating a predetermined frequency sequence with predetermined timing by means of a first and a second phase locked loop circuits each having at least one controllable oscillator unit according to claim 11.

Accordingly, the method comprises: generating in the first of the two phase locked loop circuits a frequency of the frequency sequence and providing said frequency as output; controlling the at least one controllable oscillator unit in the second phase locked loop circuit by means of a control value corresponding to the next frequency of the frequency sequence; and providing the said next frequency as output.

The method may further comprise using the actual control value inputted to a controllable oscillator unit to update the respective stored control value corresponding to the actual generated frequency.

### BRIEF DESCRIPTION OF THE DRAWINGS

These and other aspects of the invention will be apparent from and elucidated with reference to the embodiment(s) described hereinafter. In the following drawings:

FIG. 1A illustrates time constraints of frequency hopping in WiMax UWB by means of a time diagram, wherein frequency hopping in three bands is used;

FIG. 1B illustrates a ping-pong configuration of two parallel arranged PLL circuits for fast frequency hopping;

FIG. 1C illustrates a frequency generating system comprising three parallel arranged complete PLL circuits, which can be used e.g. in a WiMax UWB system;

FIG. 2A shows a frequency generating system in accordance to one aspect of the invention, in which three parallel VCOs with adjacent control value storage means selectively share the remaining elements of one common PLL circuit;

FIG. 2B shows a frequency generating system in accordance to another aspect of the invention, in which one controlled oscillator is connected to a bank of control value storage means, the elements of which are selectively connectable to the input of the controlled oscillator;

FIG. 2C illustrates the process of frequency generation in a frequency synthesizer system with the ping-pong configuration in accordance to the invention;

FIG. 3 shows one embodiment of two frequency generation arrangements of the invention in a ping-pong configuration; and

FIG. 4 shows a schematic flow diagram of the operation of preferred embodiments of the present invention.

### DETAILED DESCRIPTION OF EMBODIMENTS

Firstly, in this document, the number of possible frequencies to be generated is denoted with the symbol n. So, for example, in WiMedia UWB, n usually equals 3, since the system hops over the three bands within a band group.

Secondly, only by way of example, in the following it is assumed that for the controllable or controlled oscillators, voltage controlled oscillators (VCO) are used. As mentioned above, in case of the controllable oscillator being a voltage controlled oscillator, the control signal is a voltage signal. However, a controllable oscillator in the meaning of the present invention can alternatively be implemented as controlled by other means than a control voltage, e.g. a digital control word, in case of a digitally controlled oscillator (DCO) or a current, in case of a current controlled oscillator (CCO).

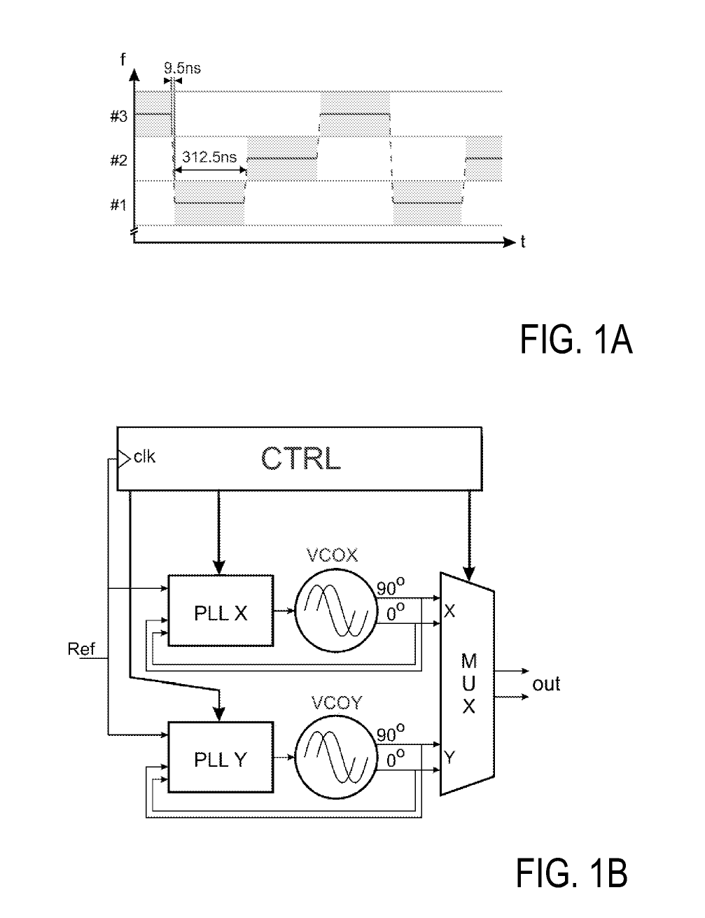

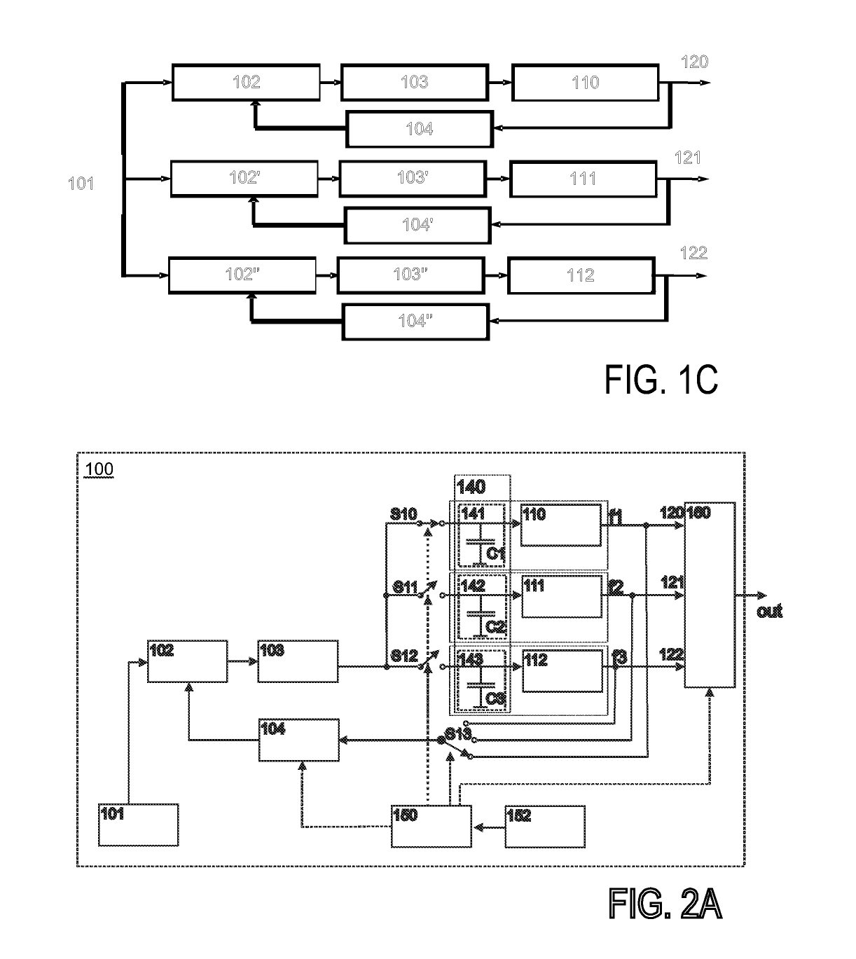

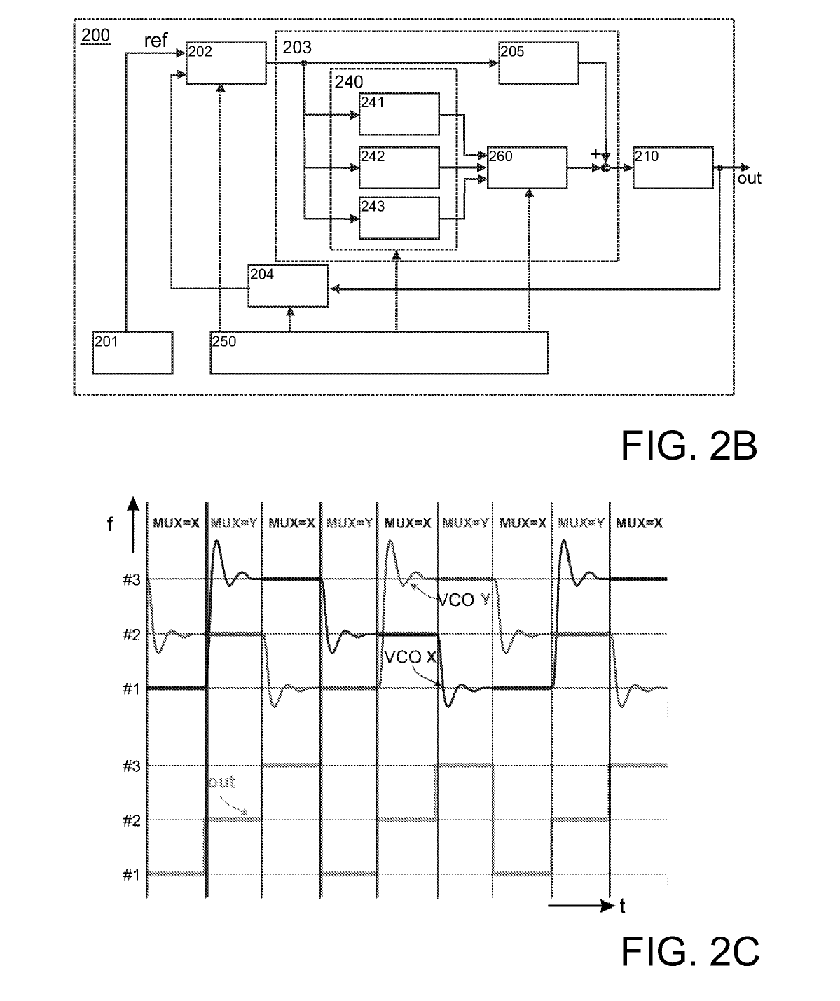

Now with reference to FIG. 2A, a first embodiment in accordance with a one aspect of the invention will be described. In comparison to FIG. 1C, in FIG. 2A between the low pass filter 103 and each voltage controlled oscillator (VCO) 110, 111, and 112, respectively, is arranged a respective switch S10, S11, and S12, respectively, and a respective control value storage or maintaining means 141, 142, 143, e.g. a capacitor C1, C2, and C3, respectively. As one alternative to the capacitors, as maintaining means a dedicated track-and-hold or sample-and-hold circuit (of which many realizations exist in literature) can be placed between the loop filter unit 103 and the respective VCO 110, 111, and 112, respectively.

It is worth to be noted that one feature of the invention is that there is provided some kind of memory bank 140 in which the required oscillator input values for each of the n output frequencies can be stored. Such memory banks may consist of analog capacitors C1, C2, and C3, respectively, in the case of an oscillator with an analog tuning input, as illustrated in FIG. 2A. Further, the number of memory elements has been set to be three in this example, i.e. to be equal to n such that there is one memory element per output frequency.

It will be appreciated that in a digital implementation of the synthesizer the memory bank 140 may be implemented by means of respective digital registers, i.e. in the case of a digitally controlled oscillator (DCO), where the control value is represented by a respective digital control word. Also a hybrid form is possible, where a coarse frequency tuning is made by means of a digital control value in addition to an analog frequency fine-tuning. In this case, the memory bank 140 may consist of both digital registers as well as analog storage elements such as capacitors, for example.

In FIG. 2A, the whole circuit arrangement 100 is controlled by a control unit 150, which as far as required for the system as depicted in FIG. 2A controls the required periodical switching operations for the consecutive recalibration of the respective PLL subsystems. The control unit 150 may be a dedicated ASIC device, which comprises hard-wired control circuitry. Alternatively, the control unit can be implemented as a processor or microcontroller connected to a memory 152 for storing respective instructions, which when run on the controller cause the controller to perform the predetermined control of the frequency synthesizer system. Further, the memory 152 may be used to store certain control parameters of the system, such as the hopping sequence for the frequencies to be generated.

As a result, the basic PLL circuit components, i.e. phase comparator unit 102, the filter unit 103, and the frequency divider unit 104 are only present once, i.e. are reused for each frequency f1, f2, and f3 to be generated. It goes without saying that according to the described principle a system can be setup with any desired number of different frequencies.

It is noted that re-using the phase detector is possible if only the frequency of the carrier signal is of interest. Usually, for example in UWB, also the phase should be accurately controlled. Leaving the oscillator running freely may cause phase drift and re-locking would be necessary before the oscillator could be used as a carrier generator. Hence, if also the phase is important, two complete PLL circuits in ping-pong configuration can be used. In that case, for example, each of the two PLL circuits can then be constructed as will be described herein below in connection with the embodiment illustrated in FIG. 2B.

Further, the feedback lines from each VCO output 120, 121, and 122, respectively, are selectively switchable connected to the frequency divider unit 104 via a (1:n) multi switch S13, where n=3 in the WiMedia UWB embodiment. The multi switch S13 can be implemented, for instance, by means of a multiplexer unit.

Furthermore, in FIG. 2A, in the shown state, the frequency reference unit 101, the phase comparator unit 103, the VCO 110, and the frequency divider unit 104 form an active PLL circuit.

After the first frequency f1 has reached a stable value, i.e. the VCO 110 is calibrated, switch S10 can be opened. Then, the final control value is stored on the control value storage unit 141, i.e. the capacitor C1. The stored control value, supplied as control signal to the controlled oscillator, will keep the oscillator, i.e. the VCO 110, at the predetermined frequency f1. Thus, a big deal of the hardware, namely the phase detector 102, the loop filter unit 103 and the frequency divider unit 104 can be shared between several PLL circuits, i.e. in FIG. 2A between a total of three PLL circuits.

The time period, in which the respective VCO stays only under control of the control value, i.e. the voltage maintained in the respective control value storage unit 141, 142, or 143, respectively, is preferably kept as small as required to avoid the respective VCO drifting out of a predetermined tolerance window. As will be discussed below, this solution is also applicable to multiple PLL configurations, as in accordance with a further development of the invention.

It will be appreciated that in case of a digital implementation of the PLL circuits, the concept is applied by implementing the control value storage unit for example by means of a respective register in front of the respective digitally controlled oscillator.

In operation of the circuit arrangement 100, after a short transient, the VCO 110 will provide at system output 120 an approximately constant frequency f1, since the control value storage unit 141, i.e. the capacitor C1, maintains its recent input voltage, which corresponds to the last calibrated control value for the VCO 110, when disconnected, by opening switch S10, from the rest of the PLL circuit.

For further illustration, it is assumed that next the VCO 111 is connected by closing switch S11 to the low pass filter unit 103 and via the multi(plexer) switch S13 to the divider unit 104. Now, after a respective transient VCO 111 will provide at its output 121 an approximately constant frequency f2.

It goes without saying, that the adjustment or periodical calibration of VCO 112 is done just as described in connection with the VCOs 110 and 111.

Thus, each PLL subsystem provides at its respective output 120, 121, and 122, respectively, a frequency signal f1, f2, and f3, respectively, which no longer requires a respective complete own PLL circuit. That is to say, by means of the stored or maintained control values, which are held in the respective control value storage unit 141, 142, and 143, respectively, the VOCs 110, 111, and 112 are operated most of the time autonomously, due to the respective control voltage value stored in the associated capacitor C1, C2, and C3, respectively.

It goes without saying that, if the divider ratio, implemented in the frequency divider unit 104, is modified during the above mentioned switching operations the three frequency signals f1, f2, and f3, respectively, will be shifted accordingly. Hence, the respectively stored control values in the control value storage means 141, 142, and 143, respectively, will be adjusted to corresponding different control values.

Finally, the VCO output signals, i.e. the frequencies f1, f2 and f3, are supplied to or feed into a multiplexer unit 160. The multiplexer unit 160 may be controlled by the controller 150 to pass the required VCO output signals f1, f2 and f3, respectively, in accordance with the desired hopping sequence and timing to the system output OUT.

As already discussed in connection with FIG. 2A, one feature of the invention is the use of memory banks for storing required oscillator input values for each of the n desired output frequencies. An alternative implementation of the PLL plus memory bank is shown in FIG. 2B. The whole circuit arrangement 200 is controlled by a control unit 250, which as far as required for the system as depicted in FIG. 2B controls the required periodical switching operations. Again, the control unit may be implemented as a processor or microcontroller with or connected to a memory storage for storing respective instructions, which when run on the controller cause the controller to perform the predetermined control of the frequency synthesizer system. Further, memory storage may be used to store certain control parameters of the system, such as the hopping sequence for the frequencies to be generated.

Further the arrangement 200 comprises a reference frequency generation unit 201, which provides the phase detector (PD) 202 with the reference frequency as input. A reference frequency may be generated e.g. by a PLL controlled by a quartz crystal.

In this design, the memory bank 240 is actually part of the PLL loop filter 203, which is comprised of a linear branch with an amplifier unit 205 for proportional gain and a non-linear branch with the integral part of the loop filter, i.e. the integrators 241, 242, and 243, respectively, which can be updated automatically during operation. It goes without saying that this was also possible for the arrangement shown in FIG. 2A, where the capacitors being part of the loop filter. One difference between the arrangements FIGS. 2A and 2B is that the arrangement of FIG. 2A is a complete synthesizer that shares the PLL components, i.e. phase detector, divider and even loop filter, while the arrangement of FIG. 2B depicts a single PLL that uses a memory bank 240.

One of the integrators 241, 242, and 243, respectively, can be selected by the control unit 250 by means of a (1:n) multiplexer unit 260, the output signal of the selected integrator is combined with the linear signal of the loop filter. Then, the complete control signal is used as control signal input to the controlled oscillator 210.

As in the arrangement of FIG. 2A, the output of the oscillator 210 is fed back to the PD 202 via a frequency divider unit 204.

According to the invention, each integrator 241, 242, and 243, respectively, of the integral part of the loop filter 203 corresponds to one control value storage unit or memory element, respectively. Thus, the arrangement 200 comprises n memory elements rather than one, as is usual in a PLL integrator; in the illustrated embodiment bay way of example n has been chosen to be 3. The appropriate element is updated by selecting only one for writing into. The memory elements may again be capacitors with series switches to connect to or disconnect from the output of PD 202, or, alternatively, digital registers that have an “enable” input that enables writing into them. The non-selected memory elements maintain their data unaltered.

It is worth noting that the loop filter 203 of PLL circuits usually consists out of a combination of capacitors and resistors to create the correct control behavior, where the dominant pole is formed by a capacitor. With respect to the above described solution, this capacitor may also be used during the settling phase of the PLL circuit in its original way, i.e. as voltage value storage as required for implementing the functionality of the control value storage unit.

This part of the implementation takes care that the current oscillator input may be used to update the memory bank's corresponding entry to keep it up to date in case the calibrated value may become invalid due to temperature or supply voltage changes for example.

Further, by having the (n:1) multiplexer 260 select the appropriate memory element to control the oscillator care is taken that the oscillator's control will be set to the value stored in the memory bank 240 at the entry corresponding to the newly wanted frequency. This step makes sure that the oscillator is already very close to or exactly at the wanted phase-frequency lock, thus ensuring that such a lock is obtained extremely fast, e.g. well within 300 ns as required in the WiMedia UWB example.

It is noted that it is also possible that, instead of a memory bank 240 as part of the PLL circuit, an external memory bank is provided that can be accessed from the control unit of the PLL circuits. In case of a ping-pong configuration with two PLL circuits, such an external memory bank may consist of (2 n) elements, i.e. n elements per PLL circuit, where each PLL circuit has access to its own part of the memory bank.

Then oscillator's control is set to the value stored in the memory bank 240 at the entry corresponding to the newly wanted frequency by pre-loading the internal integrator of the PLL circuit with the control value that is stored in the memory bank 240.

It is worth noting that the memory bank 240 may be reduced to n elements, when both PLL circuits of a ping-pong configuration share the same elements.

For the circuit in FIG. 2B to work correctly there needs to be a calibration phase in which the memory elements are filled with the correct values. This calibration may be executed only once, e.g. at production test for example or each time a data transmission should occur, or anything in between, e.g. each time the system starts up, or on a significant temperature change. The calibration process consists of locking both PLL circuits of a ping-pong configuration to each of the wanted carriers and then storing the oscillator control value in the memory bank 240.

It is worth to be noted that with the structure of the arrangement 200 of FIG. 2B the phase of the actual output frequency is always accurately controlled. Thus phase drift, as may be possible with a free running oscillator, is effectively avoided.

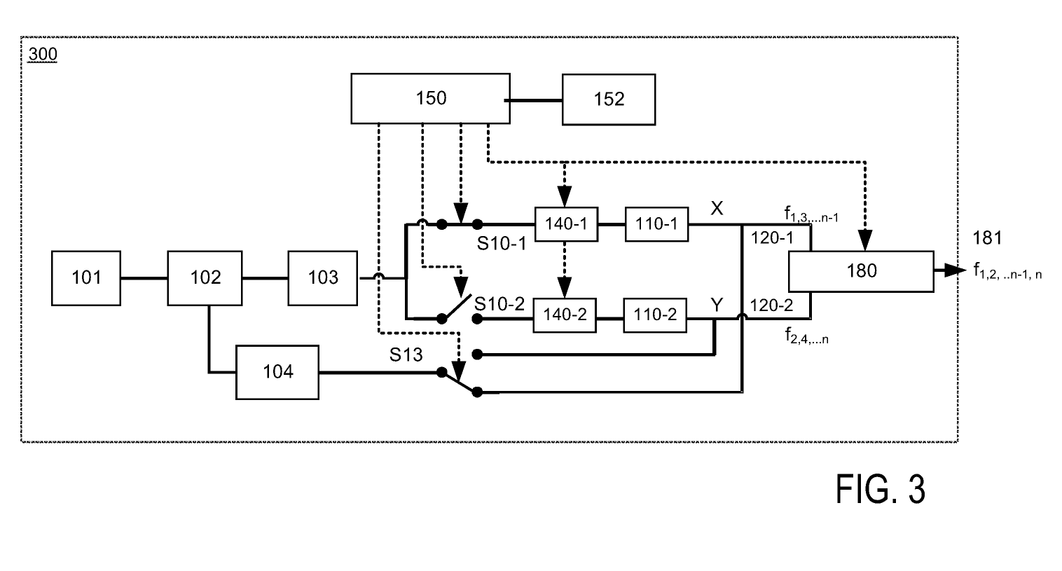

To further enhance the generation of a frequency sequence, in particular with respect to achieved speed for the frequency hopping rate, a further development of the present invention is illustrated in FIG. 3, in which a ping-pong configuration is employed, in which basically any one of the arrangements described together with FIGS. 2A and 2B can be implemented. In FIG. 3 the switching means are denominated S10-1 and S10-2, the control value storage means are denominated 140-1 and 140-2, the controlled oscillators are denominated 110-1 and 110-2 and the oscillator outputs are denominated 120-1 and 120-2.

Accordingly, the ping-pong architecture is composed of two PLL circuits, e.g. as shown in FIG. 2A or 2B, and a multiplexer unit 180. A control unit 150 coordinates operation, which is described shortly in the following. As it regards specific implementation of the control unit, reference is made to the description in connection with FIG. 2A.

The general function of the control unit is to tell each PLL circuit which frequency to generate and to toggle the multiplexer unit (MUX) 180. If, for example, the PLL branch, marked with X, generates the current LO frequency and the MUX 180 selects output 120 to pass to, e.g. the frequency conversion part of a transceiver, then the PLL branch, marked with Y, i.e. more particular the VCO 111, is told to lock to the next required frequency in the hopping sequence, e.g. TFC in WiMedia lingo. Then, when this next frequency is needed, the control unit 150 toggles the MUX 180 to select PLL branch Y and then tells PLL branch X, i.e. the VCO 110, to generate the frequency that is now the next frequency, et cetera.

The above described process of hopping frequency sequence generation is illustrated by means of FIG. 2C.

Accordingly, by means of the frequency synthesizer arrangements 300 as illustrated in FIG. 3, a desired hopping frequency sequence can be implemented with low hardware requirements.

Accordingly both selectively switchable PLL branches of the ping-pong configuration are identical in design. Hence, both can be configured to generate the complete set of LO frequencies that may be required in the system, such as the frequency sequence for WiMedia lingo.

In the description, the number of possible LO frequencies had been denoted with the symbol n. So, for WiMedia UWB, n usually equals 3, since the system hops over the three bands within a band group.

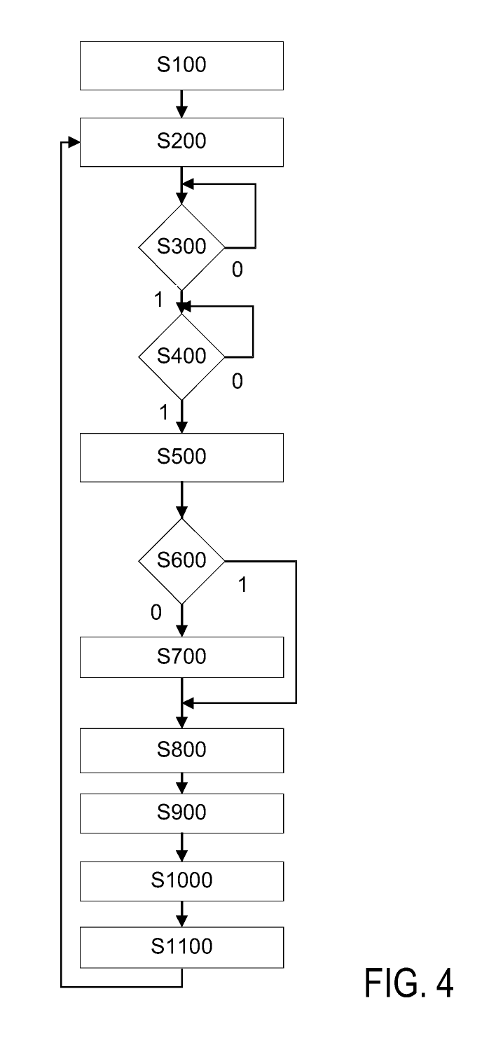

Now with respect to FIG. 4, the operation of the system shown in FIG. 3 will now be explained in detail in connection with a flowchart. It is noted that “0” denotes a logical “NO” and “1” equals a logical “YES”.

In step S100 a timer or clock is started for determining the period and timing in which a certain frequency is to be provided at the system output.

In step S200 a stored value corresponding to the next frequency fₓ₊₁ (wherein x is a sequential number indicating the actually generated frequency) to be generated is applied to one VCO_{y+1} (wherein y is a sequential number indicating the VCO actually generating output signal).

At step S300 the output of the VCO is monitored on, whether it is appropriate for being propagated to system output. If not, the PLL circuit calibrates the control value until the VCO output matches its signal tolerance band.

Then, in step S400 a second check is done on, whether the timer has expired indicating, that the next frequency of the predetermined sequence is to be passed by to the system output. If not “0”, the check is repeated until the timer has expired “1”, then the timer is reset and started over in step S500.

At S600 the controlling means may determine whether the stored value corresponding to the input voltage of the currently generating VCO is adequate for pre-calibrating the VCO next time the currently generated frequency is to be generated. If not “0”, the current VCO input voltage is used to update the corresponding value in step in S700. If so “1”, the controller 190 instructs the multiplexer unit 180 in step S800 to pass the VCO_{y+1} output signal having frequency fₓ₊₁ to the system output.

At step S900 the switches at VCO_{y+1} input and at VCO_{y+1} feedback line is opened and subsequently in step S1000 it is changed from VCO_{y+1} to VCO_{y+2} which now corresponds to VCO_{y+1} above and from signal fₓ₊₁ to signal fₓ₊₂ which now corresponds to fₓ₊₁ above.

In step S1100 the switches at the VCO_{y+1} input and feedback line are closed for calibration by the PLL.

The consecutive operation starts again at step S200.

It should be noted that the above-discussed process is one possible example for how a certain embodiment could operate. Those skilled in the art will easily identify steps, which may be modified or omitted without deviating from the scope defined by the appended claims. For example in case that two PLL circuits are employed, toggling switches in steps S900 and S1100 has no counterpart in the circuit and thus can be omitted.

While the invention has been illustrated and described in detail in the drawings and foregoing description, such illustration and description are to be considered illustrative or exemplary and not restrictive; the invention is not limited to the disclosed embodiments.

Other variations to the disclosed embodiments can be understood and effected by those skilled in the art in practicing the claimed invention, from a study of the drawings, the disclosure, and the appended claims.

In the claims, the word “comprising” does not exclude other elements or steps, and the indefinite article “a” or “an” does not exclude a plurality. “A single . . . ” or other unit may fulfill the functions of several items recited in the claims. The mere fact that certain measures are recited in mutually different dependent claims does not indicate that a combination of these measured cannot be used to advantage. A computer program may be stored/distributed on a suitable medium, such as an optical storage medium or a solid-state medium supplied together with or as part of other hardware, but may also be distributed in other forms, such as via the Internet or other wired or wireless telecommunication systems. Any reference signs in the claims should not be construed as limiting the scope.

1. Frequency generating arrangement for generation of at least two predetermined frequencies, comprising:
a phase locked loop circuit with at least two control value storage units and
at least one controlled oscillator unit;
wherein the control value storage units are configured to selectively output a control signal to the at least one controlled oscillator unit, causing generation of one of the at least two predetermined frequencies.

2. Frequency generating arrangement according to claim 1, wherein the phase locked loop circuit comprises a multi switch for connecting and disconnecting the output of one of the at least two control value storage units with the at least one controlled oscillator unit.

3. Frequency generating arrangement according to claim 1, wherein the phase locked loop circuit further comprises for each control value storage unit a corresponding controlled oscillator unit connected thereto, and a multi switch for connecting and disconnecting the output of one of the controlled oscillator units with the output of the frequency generating arrangement.

4. Frequency generating arrangement according to claim 2, further comprising a controlling unit configured to control the switching of the multi switch such that the frequency generating arrangement outputs a predetermined frequency sequence with a predetermined timing.

5. Frequency generating arrangement according to claim 1, wherein the at least two control value storage units are integrated together in a memory bank configured for storing information corresponding to the predetermined control values of the control value storage units and to selectively output one of the control values.

6. Frequency generating arrangement according to claim 1, further comprising one of a track-and-hold circuit and a sample-and-hold circuit as the control value storage unit.

7. Frequency generating arrangement according to claim 1, wherein the control value storage unit is implemented by one of analog components, digital components, and a hybrid thereof.

8. Frequency generating arrangement according to claim 7,
wherein the control value storage means comprise analogue and digital components, and
wherein the digital storage components store first part of the control value for coarse tuning of a respective voltage controlled oscillator unit connected thereto and the analogue component stores a second part of the control value for fine tuning of the controlled oscillator unit.

9. A frequency generating system comprising:
a first frequency generating arrangement and a second frequency generating arrangement in accordance with one of the claim 1, and a controlling unit and a multiplexer unit for selectively connecting only one of the outputs of the two frequency generating arrangements with an output of the system;
wherein the controlling unit controls the system to generate a predetermined frequency sequence by
controlling the two frequency generating arrangements such that during the period, in which one of the frequency generating arrangements is connected with the output of the system, the other frequency generating arrangement is controlled to lock to a next predetermined frequency of the predetermined frequency sequence, and to control the multiplexer unit pass the output of the other frequency generating arrangement to the system output after a predetermined time period; and
repeating the controlling step in order to generate the predetermined frequency sequence.

10. System according to claim 9, in a communication device which is configured for communication in accordance with a communication protocol in which a predetermined hopping frequency sequence is used.

11. Method for generating a predetermined frequency sequence with predetermined timing by a first and a second phase locked loop circuit each having at least one controllable oscillator unit, the method comprising:
generating in the first of the two phase locked loop circuits a frequency of the frequency sequence and providing said frequency as output;
controlling the at least one controllable oscillator unit in the second phase locked loop circuit by a control value corresponding to the next frequency of the frequency sequence; and
providing the next frequency as output.

12. Method according to claim 11, further comprising:
using the actual control value inputted to a controllable oscillator unit to update the respective stored control value corresponding to the actual generated frequency.
